(19) United States
(12) Patent Application Publication
(10) Pub. No.: US 2013/0082175 A1
(43) Pub. Date: Apr. 4, 2013

(54) METHOD AND PARTICLE BEAM DEVICE FOR PRODUCING AN IMAGE OF AN OBJECT

(71) Applicant: Heiner Jaksch, Heidenheim (DE)

(72) Inventor: Heiner Jaksch, Heidenheim (DE)

(21) Appl. No.: 13/564,897

(22) Filed: Aug. 2, 2012

(30) Foreign Application Priority Data
Aug. 3, 2011 (DE) 10 2011 080 341.6

(51) Int. Cl. H01J 37/26; G01N 23/225

(52) U.S. Cl. CPC H01J 37/26; G01N 23/2251
USPC 250/307; 250/310

(57) ABSTRACT

A system for producing an image of an object using a particle beam device is provided. A particle source is used to generate primary particles, in which the primary particles have a primary energy. The primary particles are delivered to an object, in which the primary particles form a particle beam. Interaction particles which are scattered back by the object in the direction of the particle source are detected with at least one energy-resolving detector. Detection signals, which are obtained through the detection, are evaluated in terms of an energy which the detected interaction particles have. The detection signals which stem from the detected interaction particles whose energy deviates by less than 500 eV from the primary energy are selected. An image of the object is produced, in which only the selected detection signals are used to produce the image.

### TECHNICAL FIELD

This application relates to a method for producing an image of an object using a particle beam device. This application furthermore relates to a particle beam device for producing an image of an object. The particle beam device is configured in particular for carrying out the method.

### BACKGROUND OF THE INVENTION

Electron beam devices, in particular scanning electron microscopes, are used to examine surfaces of objects (samples). To this end, an electron beam (referred to as primary electron beam below) is generated in a scanning electron microscope using a beam generator and focused onto an object to be examined through an objective lens. The primary electron beam is passed over the surface of the object to be examined, in the form of a raster, using a deflection apparatus. The electrons in the primary electron beam in this case interact with the object. As a result of the interaction, in particular electrons are emitted from the object surface (referred to as secondary electrons), or electrons in the primary electron beam are scattered back from the object (referred to as back-scattered electrons). The back-scattered electrons have in this case an energy up to the energy of the electrons in the primary electron beam. The secondary electrons usually have an energy of less than 50 eV. Both the secondary electrons and the back-scattered electrons are detected with a detector. The detector signal thus generated is used for image production.

Electron beam devices have a high spatial resolution, which is attained by a very small diameter of the primary electron beam in the plane of the object. The closer the object is to the objective lens of the electron beam device, the better is the resolution. For detecting the secondary electrons or back-scattered electrons, the detector is here arranged within the objective lens or in a region between the objective lens and the beam generator. The resolution also improves the faster the electrons in the primary electron beam in the electron beam device are initially accelerated and decelerated to a desired end energy at the end in the objective lens or in the region between the objective lens and the object.

Electron beam devices, which have an annular detector with a relatively large opening, are known. This opening is necessary so as to not influence the primary electron beam in the beam path of the electron beam device and to avoid possible contamination. The backward trajectories of the secondary electrons and back-scattered electrons in the electron beam device are influenced by the objective lens owing to the different energies of the secondary electrons and back-scattered electrons. The crossover of the beam of the secondary electrons is here closer to the object to be examined than the crossover of the beam of the back-scattered electrons. The beam of the secondary electrons therefore has a stronger divergence than the beam of the back-scattered electrons. However, the secondary electrons and back-scattered electrons pass along such trajectories that a large portion of the secondary electrons and back-scattered electrons passes through the opening in the detector and is thus not detected.

Known from the prior art is an electron beam device which has a first detector and a second detector, which each have an opening. The first detector and the second detector are arranged such that they are offset relative to each other along the optical axis of the electron beam device. The first detector, which is arranged near the object, here serves for detecting the electrons which exit the object or are scattered back by the object under a relatively large solid angle, while the second detector, which is arranged in the region of the beam generator, serves for detecting the electrons which exit from the object or are scattered back by the object under a relatively small solid angle and pass through the opening in the first detector provided for the passage of the primary electron beam.

Also known from the prior art is a particle beam device which has an energy-resolving detector. Upon irradiation of an object with an electron beam, interaction radiation in the form of X-rays is also produced. The interaction radiation is measured using the energy-resolving detector and the energy of the X-rays is determined. A semiconductor detector is used as an energy-resolving detector. It is also known from the prior art to detect interaction particles in the form of electrons using a semiconductor detector.

With respect to the prior art, reference is made to DE 198 28 476 A1, EP 0 615 123 B1, EP 2 282 197 A2, DE 10 2009 008 063 A1, DE 10 2009 024 928 A1 and U.S. Pat. No. 7,910,887 B2, which are incorporated herein by reference.

Deliberations relating to an electron beam device, which makes available a primary electron beam, generated with an electron beam generator, with a specific primary energy, have shown that electrons that are scattered back by the object in the direction of the electron beam generator and only have a slightly lower energy as compared to the electrons in the primary electron beam are scattered back relatively closely along an optical axis of the electron beam device. Said electrons are generally scattered back by a single scatter process at the object in the direction of the electron beam generator. Said back-scattered electrons, which have lost only a little energy compared to the electrons in the primary electron beam, make it possible to draw a conclusion in particular relating to the chemical bond, the oxidation state, hybridization or band gaps of the object.

Accordingly, it would be desirable to specify a method and a particle beam device, in which back-scattered electrons, which have only experienced a small energy loss during a scatter process, are detected and used for imaging purposes.

### SUMMARY OF THE INVENTION

According to the system descibed herein, a method for producing an image of an object using a particle beam device has the following steps. First, a particle source is used to generate primary particles which have a primary energy and form a primary particle beam. By way of example, electrons may be generated using an electron beam generator which have a primary energy of, for example, 1 keV to 20 keV. The primary particle beam is then guided to an object that is to be examined. By way of example, the primary particle beam may be scanned in a raster pattern over a surface of the object. Furthermore, interaction particles which are scattered back by the object in the direction of the particle source may be detected with at least one energy-resolving detector. Detection signals are generated in the process, which may be evaluated in terms of an energy which the detected interaction particles have. Afterward, the detection signals may be selected which stem from the detected interaction particles whose energy deviates by less than 500 eV from the primary energy. In an alternative embodiment, only those detection signals may be selected that stem from the detected interaction particles whose energy deviates by less than 100 eV from the primary energy. In addition, an image of the object may be produced, wherein only the selected detection signals are used to produce the image.

The method according to the system described herein makes it possible to detect and use for the imaging particles that are scattered back by an object, have only a slight energy loss owing to the scatter process and therefore have only a slightly lower energy as compared to the primary energy. In particular it is also possible to use back-scattered particles that have no energy loss. These back-scattered particles travel near the optical axis of the particle beam device. These particles are generally scattered back by a single scatter process at the object in the direction of the particle beam generator. They make it possible to draw a conclusion in particular relating to the chemical bond, the oxidation state, hybridization or band gaps of the object.

In an embodiment of the system described herein, provision is additionally or alternatively made for the detection signals to be selected such that pulse amplitudes of the detection signals are evaluated. The pulse amplitudes provide information relating to the energy and the number of the detected interaction particles per energy interval. It is possible, for example, to use a semiconductor detector for the detection. In an embodiment of the method according to the system described herein, provision is in particular alternatively or additionally made for the detection to take place using a silicon drift detector.

In a further embodiment of the method according to the system described herein, provision is additionally or alternatively made for the image of the object to be produced using an electron beam device, an ion beam device, a scanning electron microscope or a transmission electron microscope.

According furher to the system described herein, a particle beam device for producing an image of an object may have the following features:
at least one particle source for generating primary particles, wherein the primary particles have a primary energy and wherein the primary particles form a primary particle beam;
at least one objective lens for focusing the primary particle beam onto an object;
at least one energy-resolving first detector for detecting interaction particles and for generating detection signals on the basis of the detected interaction particles, wherein the interaction particles are scattered back at the object in the direction of the particle source; and
at least one evaluation unit for evaluating an energy of the detected interaction particles, wherein the evaluation unit may have at least one selection unit for selecting the detection signals that stem from detected interaction particles whose energy deviates by less than 500 eV, for example by less than 100 eV, from the primary energy.

With the particle beam device according to the system described herein it is possible in particular for the above-noted method to be carried out. With respect to the advantages, reference is made to the statements made further above.

In an embodiment of the particle beam device according to the system described herein, provision is additionally or alternatively made for the energy-resolving detector to be configured as a silicon drift detector. However, the system described herein is not limited hereto. Rather, any detector suitable for resolving an energy of detected particles may be used.

In a further embodiment of the particle beam device according to the system described herein, provision is additionally or alternatively made for the evaluation unit to comprise a pulse-amplitude evaluation unit. Using the pulse-amplitude evaluation unit, it is possible to determine the energy of the detected interaction particles.

In a further embodiment of the particle beam device according to the system described herein, provision is additionally or alternatively made for the energy-resolving first detector to be arranged between the particle source and the objective lens. Provision if furthermore made, for example, for the particle source to be configured as an electron source. In a still further embodiment, provision is additionally or alternatively made for the interaction particles to be back-scattered electrons.

In another embodiment of the particle beam device according to the system described herein, provision is additionally or alternatively made for at least one second detector to be arranged between the particle source and the objective lens. The second detector is arranged such that it is at a distance from the first detector. For example, the distance between the first detector and the second detector along the optical axis may be at least 25%, for example approximately 50% to 90%, of the distance between the second detector and the focal plane of the objective lens that focuses the primary particle beam onto the object. The second detector may be arranged for example closer to the objective lens than the first detector.

In another embodiment of the particle beam device according to the system described herein, provision is additionally or alternatively made for the first detector to have at least one first detector segment and at least one second detector segment. The first detector segment and the second detector segment may be arranged mutually spaced apart in at least one direction. By way of example, numerous detector segments may be provided, which are arranged symmetrically around the optical axis, for example in the form of a semicircle.

In another embodiment of the particle beam device according to the system described herein, provision is additionally or alternatively made for a control grid to be arranged between the first detector and the second detector. The control grid makes it possible, using a high voltage applied to the control grid, to prevent interaction particles having an energy that is considerably lower than the primary energy from reaching the energy-resolving first detector. By way of example, interaction particles having an energy of, for example, more than 500 eV or more than 100 eV below the energy of the electrons in the primary electron beam may be prevented from reaching the energy-resolving first detector. Rather, said interaction particles may be deflected by the control grid. By way of example, they may be deflected in the direction of the second detector and detected by the latter.

In another embodiment of the particle beam device according to the system described herein, provision is additionally or alternatively made for the particle beam device to be configured as an electron beam device, an ion beam device, a scanning electron microscope or a transmission electron microscope.

### BRIEF DESCRIPTION OF THE DRAWINGS

Embodiments of the system described herein will be explained using the figures, which are briefly described as follows.

FIG. 1 shows a schematic view of a first embodiment of a scanning electron microscope;

FIG. 2 shows a schematic view of a second embodiment of a scanning electron microscope;

FIG. 3 shows a schematic view of a third embodiment of a scanning electron microscope;

FIG. 4 shows a schematic view of a fourth embodiment of a scanning electron microscope;

FIG. 5 shows a schematic view of an energy-resolving detector; and

FIG. 6 shows a schematic view of a process sequence of a method for producing an image of an object.

### DETAILED DESCRIPTION OF VARIOUS EMBODIMENTS

The system described herein will be described below by way of example with reference to a scanning electron microscope. However, it is not restricted to scanning electron microscopes but is suitable for any particle beam device, as already explained above.

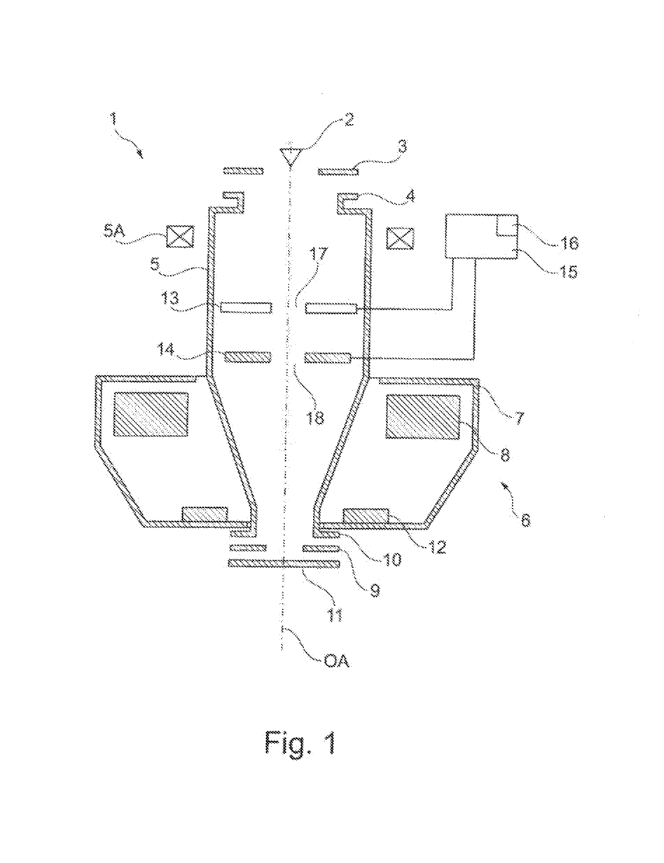

FIG. 1 shows a schematic view of a first embodiment of a scanning electron microscope 1. The scanning electron microscope 1 has a beam generator 2 in the form of an electron beam generator (cathode), a first electrode 3 and a second electrode 4 in the form of an anode. The second electrode 4 is at the same time one end of a beam-guiding tube 5 of the scanning electron microscope 1.

By way of example, the beam generator 2 is configured as a thermal field emitter. Electrons emerging from the beam generator 2 are accelerated to a potential (anode potential) owing to a potential difference between the beam generator 2 and the second electrode 4. The electrons form a primary electron beam.

Arranged on the beam-guiding tube 5 are a condenser lens 5A and also an objective lens 6. The objective lens 6 has a hole through which the beam-guiding tube 5 is guided through a pole shoe 7. Arranged in the pole shoe 7 is a coil 8. An electrostatic delay apparatus is arranged downstream of the beam-guiding tube 5 in the direction of an object 11 to be examined and pointing away from the beam generator 2. Said electrostatic delay apparatus has an individual electrode 9 and a tube electrode 10. The tube electrode 10 is formed at one end of the beam-guiding tube 5 which lies opposite the object 11. Consequently, the tube electrode 10 together with the beam-guiding tube 5 is at the potential of the second electrode 4 (i.e. at anode potential). In contrast, the individual electrode 9 and the object 11 are at a potential that is lower than the anode potential. In this way, the electrons in the primary electron beam can be decelerated to a desired low energy that is required for the examination of the object 11. The energy of the primary electron beam can in this case be set, for example, in a range of about 100 eV to about 30 keV. However, it is explicitly pointed out that the system described herein is not restricted to this energy range. Rather, any energy range suitable for the system described herein may be chosen.

The scanning electron microscope 1 furthermore has a raster unit 12, by which the primary electron beam can be deflected and scanned in a raster pattern over the object 11 in order to examine the object 11. In order to achieve a relatively good resolution at low energy of the primary electron beam, the object 11 is arranged relatively close to the objective lens 6. In order to detect interaction particles produced when the primary electron beam strikes the object 11, in particular secondary electrons and back-scattered electrons, a detector arrangement is arranged in the beam-guiding tube 5, specifically between the objective lens 6 and the beam generator 2. The detector arrangement has, in the embodiment illustrated here, two detectors, that is to say a first detector 13 and a second detector 14. Further embodiments provide only a single detector or more than two detectors. The first detector 13 is arranged at a distance from the second detector 14 along the optical axis OA of the scanning electron microscope 1. The first detector 13 is arranged closer to the beam generator 2 than the second detector 14. The second detector 14 is arranged in the region of the objective lens 6. With respect to the possible distance between the first detector 13 and the second detector 14, reference is made to further above. The first detector 13 furthermore is at the potential of the beam-guiding tube 5.

The first detector 13 has a first opening 17. The second detector 14, by contrast, has a second opening 18. The first opening 17 and the second opening 18 have the function that the primary electron beam from the beam generator 2 can pass through these openings 17, 18 in order to then be guided onto the object 11. The second opening 18 of the second detector 14 further has the function that interaction particles can pass from the object 11 onto the first detector 13.

The second detector 14 serves for detecting those interaction particles (secondary electrons and back-scattered electrons) that emerge from the object 11 at a relatively large solid angle or are scattered back by the object 11. The second detector 14 detects here mainly secondary electrons. Back-scattered electrons that have experienced only a small energy loss during the scatter process at the object 11, and thus have an energy that deviates by less than 500 eV, for example less than 100 eV, from the primary energy, are detected by the first detector 13. These back-scattered electrons travel from the object 11 in the direction of the beam generator 2 relatively close to the optical axis OA of the scanning electron microscope 1. The first detector 13 is configured as an energy-resolving detector, for example a semiconductor detector. Provision is in particular made for the first detector 13 to be a silicon drift detector. This will be discussed in more detail further below.

Both the first detector 13 and the second detector 14 are connected to an evaluation unit 15. The evaluation unit 15 has a pulse-amplitude evaluation unit 16, with which it is possible in particular to determine the energy of the back-scattered electrons striking the first detector 13.

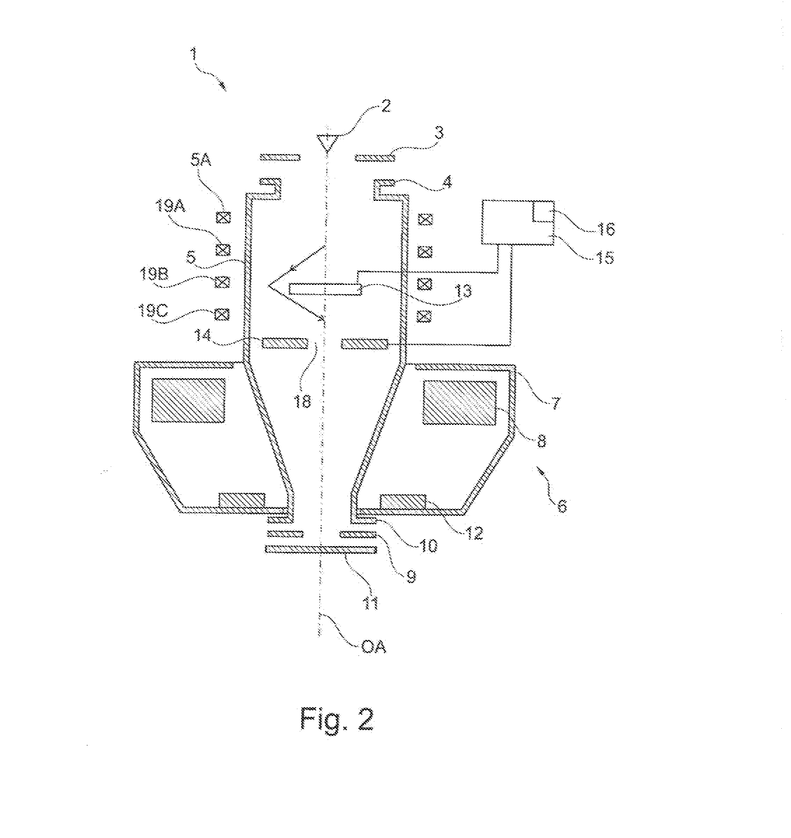

FIG. 2 shows a schematic view of a second embodiment of the scanning electron microscope 1. The embodiment in FIG. 2 is based on the embodiment in FIG. 1. Therefore, identical components are provided with identical reference symbols. Unlike the embodiment in FIG. 1, the embodiment in FIG. 2 has a first detector 13 in which no opening is located. The first detector 13 is arranged symmetrically around the optical axis OA. The primary electron beam therefore cannot pass through the first detector 13. For this reason, a first deflection unit 19A, a second deflection unit 19B and a third deflection unit 19C are arranged in the beam-guiding tube 5. The first deflection unit 19A deflects the primary electron beam away from the optical axis OA, that is to say in the direction of a wall of the beam-guiding tube 5. The second deflection unit 19B deflects the primary electron beam back in the direction of the optical axis OA. The third deflection unit 19C in turn deflects the primary electron beam such that the primary electron beam once again travels along the optical axis OA.

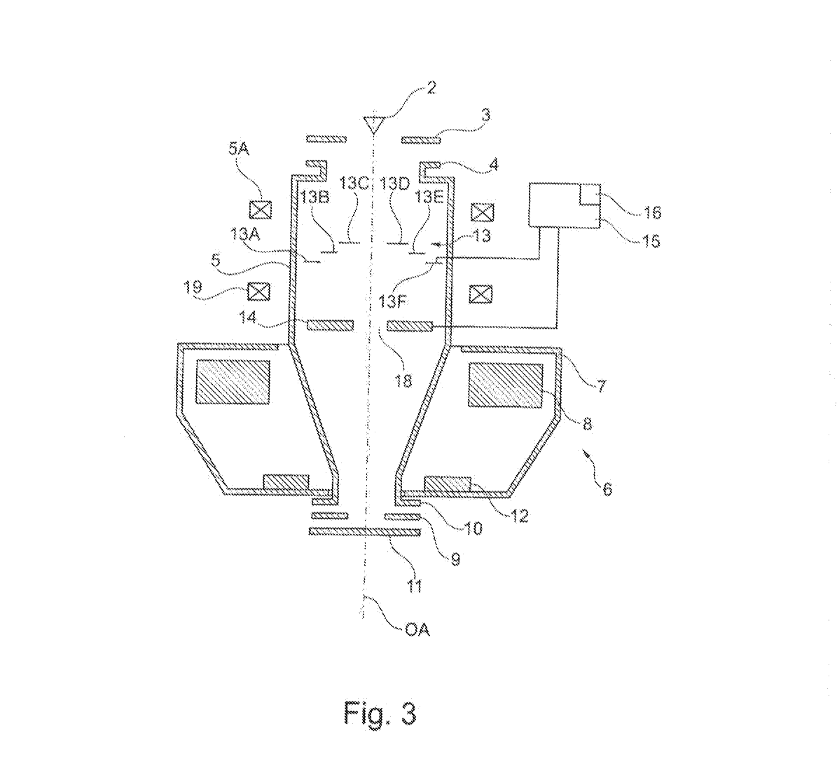

FIG. 3 shows a schematic view of a third embodiment of the scanning electron microscope 1. The embodiment in FIG. 3 is based on the embodiment in FIG. 1. Therefore, identical components are provided with identical reference symbols. Unlike the embodiment according to FIG. 1, the embodiment according to FIG. 3 has a Wien filter 19 arranged between the first detector 13 and the second detector 14.

The second detector 13 has numerous detector segments, that is to say a first detector segment 13A, a second detector segment 13B, a third detector segment 13C, a fourth detector segment 13D, a fifth detector segment 13E and a sixth detector segment 13F. The detector segments just mentioned are arranged along a semicircle about the optical axis OA. They are arranged mutually spaced apart along the optical axis OA and in a direction perpendicular to the optical axis OA.

The Wien filter 19 serves to split the back-scattered electrons, which pass through the second opening 18 of the second detector 14, with respect to their different energies such that back-scattered electrons of a very specific energy range are guided onto a very specific detector segment 13A to 13F.

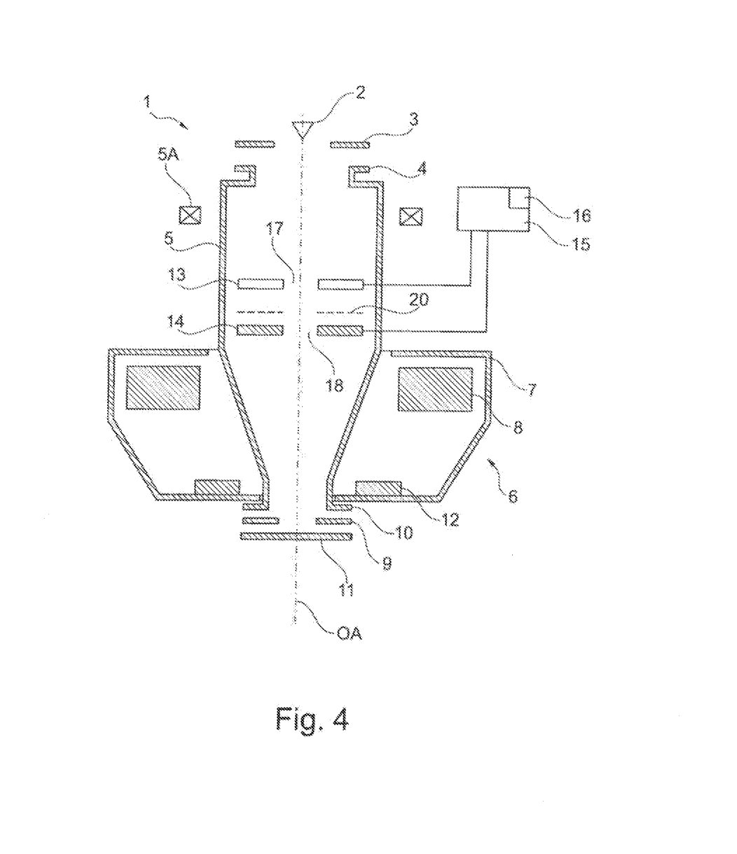

FIG. 4 shows a schematic view of a fourth embodiment of the scanning electron microscope 1. The embodiment in FIG. 4 is based on the embodiment in FIG. 1. Therefore, identical components are provided with identical reference symbols. Unlike the embodiment in FIG. 1, the embodiment in FIG. 4 has a control grid 20, arranged between the first detector 13 and the second detector 14. The control grid 20 is used to keep back back-scattered electrons and secondary electrons that have an energy that is considerably lower than the primary energy (for example energies of more than 1 keV or more than 2 keV below the primary energy). They do not reach the first detector 13. On account of the deflection of these electrons at the control grid 20, there is also the possibility that said electrons then pass in the direction of the second detector 14 and are detected there. To this end, a suitable high voltage is applied to the control grid 20. However express mention is made that the system described herein is not limited to the use of a control grid 20. Rather, in numerous embodiments of the system described herein, provision is made for a control grid 20 to not be used, as also already illustrated by the further embodiments.

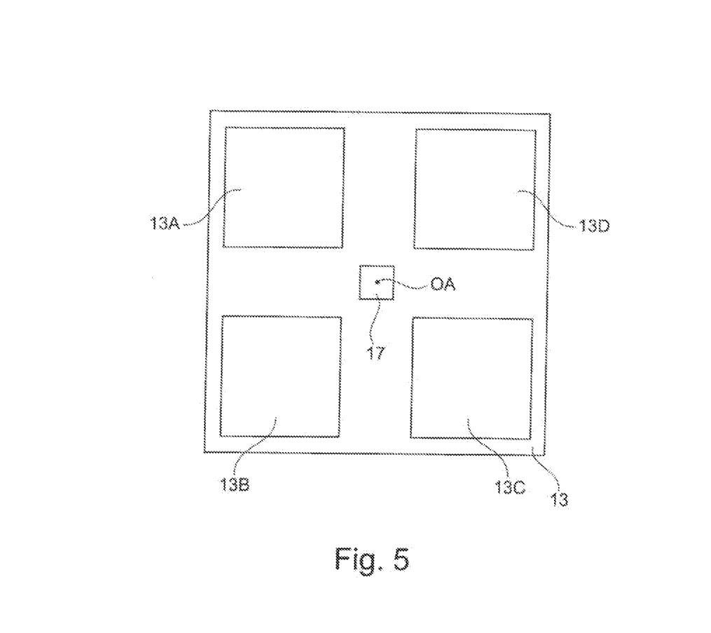

FIG. 5 shows an embodiment of a first detector 13, as can be used in the embodiment according to FIG. 1, for example. The first detector 13 is provided centrally with the first opening 17, through which the optical axis OA extends. Furthermore arranged on the first detector 13 are four detector segments, that is to say a first detector segment 13A, a second detector segment 13B, a third detector segment 13C and a fourth detector segment 13D. Each of the individual detector segments 13A to 13D is arranged in one of four quadrants of the first detector 13. Each of the previously mentioned detector segments is configured for example as a semiconductor detector, in particular as a silicon drift detector. The previously mentioned detector segments 13A to 13D are not restricted to the illustrated shape. Rather, the previously mentioned detector segments 13A to 13D can have any suitable shape. By way of example, they can also be configured as a segment of a circle or as a ring segment.

In one further embodiment of the first detector 13, the first detector 13 has an entry window in front of at least one detection area, for example at least one of the previously mentioned detector segments 13A to 13D. The entry window is configured as a film, for example. The entry window is configured such that back-scattered electrons can pass through the entry window. The entry window serves in particular to protect the detection area, which can be cooled, for example. If a sample chamber of the scanning electron microscope 1, in which the object 11 to be examined is arranged, is vented, it is ensured on account of the entry window that the detection area is not contaminated or iced up.

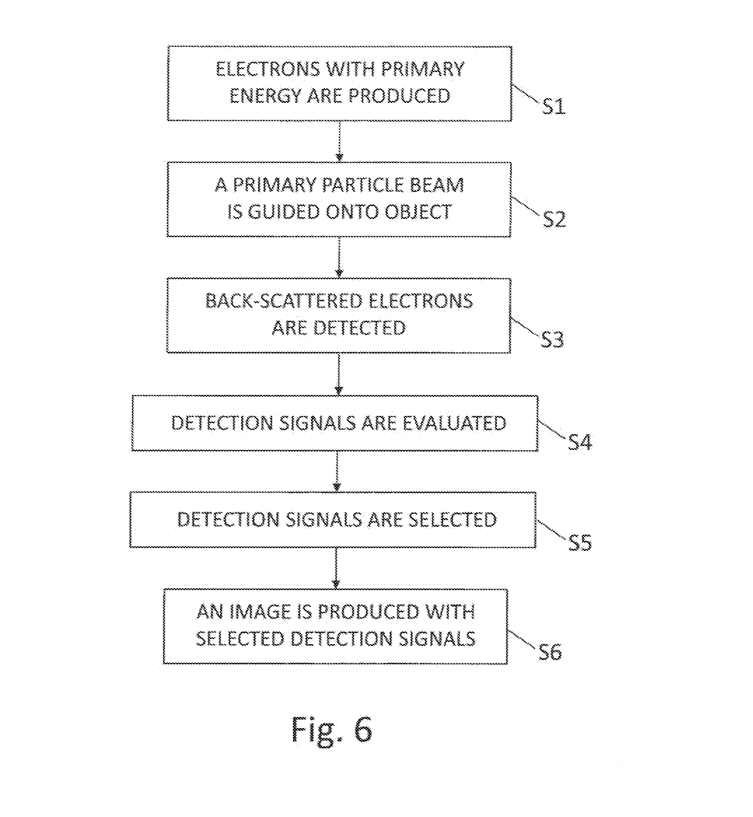

FIG. 6 shows a schematic view of a process sequence of an embodiment of the method for producing an image of an object 11 using the scanning electron microscope 1. The method can be used for any of the previously mentioned embodiments.

In step S1, first electrons having a specific primary energy are generated using the beam generator 2. Subsequently, the generated electrons are guided in the form of a primary electron beam onto the object 11 (step S2).

The back-scattered electrons produced when the primary electron beam strikes the object 11 are scattered back in the direction of the first detector 13 along the optical axis OA of the scanning electron microscope 1. They are then detected by the first detector 13 (step S3). In step S4, detection signals generated by the first detector 13 are then evaluated using the evaluation unit 15 (step S4). Detection signals, which stem from detected back-scattered electrons whose energy deviates by less than 500 eV (or by less than 100 eV) from the primary energy, are selected (step S5) on the basis of the pulse amplitudes produced by the detection signals. A significant portion of back-scattered electrons are detected whose energy deviates by less than 500 eV or by less than 100 eV from the energy of the electrons in the primary electron beam. These selected detection signals are then used to produce an image of the object 11 (step S6).

The method and the above-described embodiments of the scanning electron microscope 1 make it possible to detect back-scattered electrons, which are scattered back by the object 11, have only experienced a small energy loss during the scatter process and thus have only a slightly lower energy compared to the primary energy, and to use them for imaging purposes. The back-scattered electrons travel close to the optical axis OA of the scanning electron microscope 1. The back-scattered electrons are generally scattered back by a single scatter process at the object 11 in the direction of the beam generator 2. They make it possible to draw a conclusion in particular relating to the chemical bond, the oxidation state, hybridization or band gaps of the object 11.

Various embodiments discussed herein may be combined with each other in appropriate combinations in connection with the system described herein. Additionally, in some instances, the order of steps in the flowcharts, flow diagrams and/or described flow processing may be modified, where appropriate. Further, various aspects of the system described herein may be implemented using software, hardware, a combination of software and hardware and/or other computer-implemented modules or devices having the described features and performing the described functions. Software implementations of the system described herein may include executable code that is stored in a computer readable medium and executed by one or more processors. The computer readable medium may include volatile memory and/or non-volatile memory, and may include, for example, a computer hard drive, ROM, RAM, flash memory, portable computer storage media such as a CD-ROM, a DVD-ROM, a flash drive and/or other drive with, for example, a universal serial bus (USB) interface, and/or any other appropriate tangible or non-transitory computer readable medium or computer memory on which executable code may be stored and executed by a processor. The system described herein may be used in connection with any appropriate operating system.

Other embodiments of the invention will be apparent to those skilled in the art from a consideration of the specification or practice of the invention disclosed herein. It is intended that the specification and examples be considered as exemplary only, with the true scope and spirit of the invention being indicated by the following claims.

What is claimed is:

1. A method for producing an image of an object using a particle beam device, comprising:
generating primary particles using a particle source, wherein the primary particles have a primary energy;
delivering the primary particles to an object, wherein the primary particles form a particle beam;
detecting, using at least one energy-resolving detector, interaction particles which are scattered back by the object in the direction of the particle source;
evaluating detection signals, which are obtained through the detection, in terms of an energy of the detected interaction particles;
selecting the detection signals which stem from the detected interaction particles whose energy deviates by less than 500 eV from the primary energy; and
producing an image of the object, wherein only the selected detection signals are used to produce the image.

2. The method according to claim 1, wherein only those detection signals which stem from the detected interaction particles whose energy deviates by less than 100 eV from the primary energy are selected.

3. The method according to claim 1, wherein the detection takes place using a silicon drift detector.

4. The method according to claim 1, wherein the detection signals are selected such that pulse amplitudes of the detection signals are evaluated.

5. The method according to claim 1, wherein the image of the object is produced using an electron beam device, an ion beam device, a scanning electron microscope or a transmission electron microscope.

6. A particle beam device for producing an image of an object, comprising:
at least one particle source for generating primary particles, wherein the primary particles have a primary energy, and wherein the primary particles form a primary particle beam;
at least one objective lens for focusing the primary particle beam onto an object;
at least one energy-resolving first detector for detecting interaction particles and for generating detection signals on the basis of the detected interaction particles, wherein the interaction particles are scattered back at the object in the direction of the particle source; and
at least one evaluation unit for evaluating an energy of the detected interaction particles, wherein the evaluation unit has at least one selection unit for selecting the detection signals that stem from detected interaction particles whose energy deviates by less than 500 eV from the primary energy.

7. The particle beam device according to claim 6, wherein the selection unit is adapted to select the detection signals that stem from detected interaction particles whose energy deviates by less than 100 eV from the primary energy.

8. The particle beam device according to claim 6, wherein the energy-resolving first detector is configured as a silicon drift detector.

9. The particle beam device according to claim 6, wherein the evaluation unit includes a pulse-amplitude evaluation unit.

10. The particle beam device according to claim 6, wherein the energy-resolving first detector is arranged between the particle source and the objective lens.

11. The particle beam device according to claim 6, wherein the particle source is configured as an electron source.

12. The particle beam device according to claim 6, wherein the interaction particles are back-scattered electrons.

13. The particle beam device according to claim 6, further comprising:
at least one second detector arranged between the particle source and the objective lens, wherein the second detector is at a distance from the first detector.

14. The particle beam device according to claim 13, wherein the second detector is arranged closer to the objective lens than the first detector.

15. The particle beam device according to claim 6, wherein the first detector has at least one first detector segment and at least one second detector segment, and wherein the first detector segment and the second detector segment are arranged mutually spaced apart in at least one direction.

16. The particle beam device according to claim 13, further comprising:
a control grid for selecting interaction particles on the basis of energy of the interaction particles that is arranged between the first detector and the second detector.

17. The particle beam device according to claim 6, wherein the particle beam device is configured as an electron beam device, an ion beam device, a scanning electron microscope or a transmission electron microscope.
